(19) United States
(12) Patent Application Publication
(10) Pub. No.: US 2013/0335893 A1
(43) Pub. Date: Dec. 19, 2013

(54) Hinge Device and an Electronic Apparatus Comprising the Same

(71) Applicant: WISTRON CORPORATION, New Taipei City (TW)

(72) Inventors: Chen-Yi Liang, New Taipei City (TW); Cheng-Hsiang Chuang, New Taipei City (TW)

(73) Assignee: Wistron Corporation, New Taipei City (TW)

(21) Appl. No.: 13/846,865

(22) Filed: Mar. 18, 2013

(30) Foreign Application Priority Data
Jun. 15, 2012 (TW) 101121541

(51) Int. Cl. G06F 1/16; H05K 5/02

(52) U.S. Cl. CPC G06F 1/1681; H05K 5/0226
USPC 361/679.01; 16/342

(57) ABSTRACT

A hinge device includes a shaft, first and second positioning mechanisms and a coupling member. The coupling member includes a surrounding portion rotatably surrounding a surrounding segment of the shaft, and having an inner friction surface that is in contact with an outer surface of the surrounding segment to produce a first frictional force and two side friction surfaces that respectively abut against the first and second positioning mechanism to produce second and third friction forces.

### CROSS-REFERENCE TO RELATED APPLICATION

This application claims priority of Taiwanese Patent Application No. 101121541, filed on Jun. 15, 2012, the disclosure of which is incorporated herein by reference.

### BACKGROUND OF THE INVENTION

1. Field of the Invention

The invention relates to a hinge device, and more particularly to a compact hinge device and an electronic apparatus comprising the hinge device.

2. Description of the Related Art

A hinge device is widely applied in a personal electronic apparatus for connecting two electronic units, e.g. a screen and a host of a notebook computer, which need pivoting relative to each other. The hinge device not only needs a movable mechanism that enables the electronic units to pivot relative to each other, but is also required to ensure that the electronic units are secured relative to each other when no force is applied thereto for pivoting them relative to each other. In other words, the hinge device must provide a sufficient torque to avoid damages of the electronic apparatus due to accidental relative rotation and collision of the electronic units. With the increasing miniaturization of the personal electronic apparatus, there is a need for reducing the size of the hinge device accordingly.

Referring to FIG. 1, a small-sized hinge device 1 in the prior art includes a support stand 11, a shaft 12 secured to the top of the support stand 11 and extending transversely as a cantilever, and a coupling member 13 rotatably surrounding the shaft 12. The coupling member 13 includes a surrounding surface (not shown) that surrounds an outer surface of the shaft 12 in a close-fitting manner. The support stand 11 and the coupling member 13 are respectively fastened to two electronic units (not shown) that need pivoting relative to each other. When no force is applied for pivoting the two electronic units relative to each other, the close-fitting contact between the outer surface of the shaft 12 and the surrounding surface of the coupling member 13 may provide a frictional force to keep the two electronic units in a fixed position relative to each other and thus avoid accidental relative rotations therebetween. When a force sufficient to overcome the frictional force is applied to the electronic units, since the coupling member 13 rotatably surrounds the shaft 12, the two electronic units can be pivoted relative to each other.

However, as the hinge device 1 is fixed merely by friction produced between the outer surface of the shaft 12 and the surrounding surface of the coupling member 13, the area of the outer surface of the shaft 12 is required to be large enough to produce the necessary frictional force and consequently, it is difficult to further reduce the axial diameter of the shaft 12. Moreover, under the current design of the hinge device 1, it is also difficult to increase the torque provided by the shaft 12 without increasing the likelihood of a fracture in the shaft 12 or shortening the service life of the hinge device 1. In addition, since the shaft 12 is in the form of a cantilever that is connected to the support stand 11, the shaft 12 may easily wobble relative to the support stand 11, which can easily damage the electronic apparatus.

### SUMMARY OF THE INVENTION

Therefore, an object of the present invention is to provide a compact hinge device having a sufficient torque and an electronic apparatus comprising the hinge device.

According to one aspect of this invention, there is provided a hinge device that includes a shaft unit and a coupling member.

The shaft unit includes a shaft, a first positioning mechanism and a second positioning mechanism. The shaft includes a first positioning segment and a second positioning segment at two opposite ends of the shaft and a supporting segment between the first positioning segment and the second positioning segment. The first positioning segment includes a securing portion. The second positioning segment includes a threaded portion. The first positioning mechanism is disposed at the first positioning segment between the securing portion and the supporting segment and includes a stop portion that is disposed on the first positioning segment and that is formed integrally as one piece with the shaft. The second positioning mechanism is disposed at the second positioning segment and includes a screw nut that is screwed on the threaded portion.

The coupling member includes a surrounding portion that rotatably surrounds the supporting segment of the shaft and an engaging portion that extends from the surrounding portion in a direction away from the shaft. The surrounding portion has an inner friction surface that surrounds an outer surface of the supporting segment and two side friction surfaces that are respectively at two opposite sides of the surrounding portion. The inner friction surface and the outer surface of the supporting segment are in contact with each other so as to produce a first frictional force. The screw nut is screwed in a direction towards the first positioning mechanism to allow the surrounding portion of the coupling member to be sandwiched between the first positioning mechanism and the second positioning mechanism, such that the two side friction surfaces of the coupling member respectively abut against the first positioning mechanism and the second positioning mechanism to respectively produce a second friction force and a third friction force therewith.

According to another aspect of this invention, there is provided an electronic apparatus including a first unit, a second unit and a hinge device that connects the first unit and the second unit. The hinge device enables the first unit and the second unit to pivot relative to each other and includes a shaft unit and a coupling member.

The shaft unit includes a shaft, a first positioning mechanism and a second positioning mechanism. The shaft includes a first positioning segment and a second positioning segment at two opposite ends of the shaft, and a supporting segment between the first positioning segment and the second positioning segment. The first positioning segment includes a securing portion that is fastened to the first unit. The second positioning segment includes a threaded portion. The first positioning mechanism is disposed at the first positioning segment between the securing portion and the supporting segment and includes a stop portion that is disposed on the first positioning segment and that is formed integrally as one piece with the shaft. The second positioning mechanism is disposed at the second positioning segment and includes a screw nut that is screwed on the threaded portion.

The coupling member includes a surrounding portion that rotatably surrounds the supporting segment of the shaft and an engaging portion that extends from the surrounding portion in a direction away from the shaft and that is secured to the second unit. The surrounding portion has an inner friction surface that surrounds an outer surface of the supporting segment and two side friction surfaces that are respectively located on two opposite sides of the surrounding portion. The inner friction surface and the outer surface of the supporting segment are in contact with each other so as to produce a first frictional force. The screw nut is screwed onto the threaded portion in a direction towards the first positioning mechanism to allow the surrounding portion of the coupling member to be sandwiched between the first positioning mechanism and the second positioning mechanism, such that the two side friction surfaces of the coupling member respectively abut against the first positioning mechanism and the second positioning mechanism to respectively produce a second frictional force and a third frictional force therewith.

According to yet another aspect of this invention, there is provided an electronic apparatus including a first unit, a second unit and a hinge device that connects the first unit and the second unit. The hinge device enables the first unit and the second unit to pivot relative to each other and includes a shaft unit, two support members and a coupling member.

The shaft unit includes a shaft, a first positioning mechanism and a second positioning mechanism. The shaft includes a first positioning segment and a second positioning segment at two opposite ends of the shaft and a supporting segment between the first positioning segment and the second positioning segment. The first positioning segment includes a securing portion. The second positioning segment includes a threaded portion and a limiting portion that connects the threaded portion and the supporting segment. The first positioning mechanism is disposed at the first positioning segment between the securing portion and the supporting segment and includes a stop portion that is disposed on the first positioning segment and that is formed integrally as one piece with the shaft. The second positioning mechanism is disposed at the second positioning segment and includes a screw nut that is screwed on the threaded portion.

The support stands cooperatively support the shaft. Each of the support stands includes a base wall that is secured to the first unit and a connecting wall that is substantially perpendicular to the base wall. The connecting walls are disposed opposite to and spaced from each other. The securing portion of the shaft extends through and is fixed to the connecting wall of one of the support stands. The limiting portion extends through and is fixed to the connecting wall of the other of the support stands.

The coupling member includes a surrounding portion that rotatably surrounds the supporting segment of the shaft and an engaging portion that extends from the surrounding portion in a direction away from the shaft and that is secured to the second unit. The surrounding portion has an inner friction surface that surrounds an outer surface of the supporting segment and two side friction surfaces that are respectively located on two opposite sides of the surrounding portion. The inner friction surface and the outer surface of the supporting segment are in contact with each other to produce a first frictional force. The screw nut is screwed onto the threaded portion in a direction towards the first positioning mechanism to allow the surrounding portion of the coupling member to be sandwiched between the first positioning mechanism and the second positioning mechanism, such that the two side friction surfaces of the coupling member respectively abut against the first positioning mechanism and the second positioning mechanism to respectively produce a second frictional force and a third frictional force therewith.

According to still another aspect of this invention, there is provided an electronic apparatus including a first unit, a second unit and a hinge device that connects the first unit and the second unit. The hinge device enables the first unit and the second unit to pivot relative to each other and includes a shaft unit, a support stand and a coupling member.

The shaft unit includes a shaft, a first positioning mechanism and a second positioning mechanism. The shaft includes a first positioning segment and a second positioning segment at two opposite ends of the shaft and a supporting segment between the first positioning segment and the second positioning segment. The first positioning segment includes a securing portion. The second positioning segment includes a threaded portion and a limiting portion that connects the threaded portion and the supporting segment. The first positioning mechanism is disposed at the first positioning segment between the securing portion and the supporting segment and includes a stop portion that is disposed on the first positioning segment and that is formed integrally as one piece with the shaft. The second positioning mechanism is disposed at the second positioning segment and includes a screw nut that is screwed on the threaded portion.

The support stand supports the shaft and includes a base wall that is secured to the first unit and two connecting walls that are substantially perpendicular to the base wall and that are disposed opposite to and spaced from each other. The securing portion of the shaft extends through and is fixed to one of the connecting walls. The limiting portion extends through and is fixed to the other of the connecting walls.

The coupling member includes a surrounding portion that rotatably surrounds the supporting segment of the shaft and an engaging portion that extends from the surrounding portion in a direction away from the shaft and that is secured to the second unit. The surrounding portion includes an inner friction surface that surrounds an outer surface of the supporting segment and two side friction surfaces that are respectively located on two opposite sides of the surrounding portion. The inner friction surface and the outer surface of the supporting segment are in contact with each other to produce a first frictional force. The screw nut is screwed onto the threaded portion in a direction towards the first positioning mechanism to allow the surrounding portion of the coupling member to be sandwiched between the first positioning mechanism and the second positioning mechanism, such that the two side friction surfaces of the coupling member respectively abut against the first positioning mechanism and the second positioning mechanism to respectively produce a second frictional force and a third frictional force therewith.

The effect of the present invention lies in that, by having each of the inner friction surface and the two side friction surfaces of the surrounding portion generate a corresponding frictional force with the shaft unit, a greater surface area is provided for friction generation under the condition that the axial diameter of the shaft is limited as compared to the conventional hinge device, so that the size of the hinge device may be reduced while still providing sufficient torque for maintaining a fixed relative position between the shaft unit and the coupling member, and in turn between the first unit and the second unit of the electronic apparatus incorporating the hinge device.

### BRIEF DESCRIPTION OF THE DRAWINGS

Other features and advantages of the present invention will become apparent in the following detailed description of the embodiments with reference to the accompanying drawings, of which:

FIG. 1 is a perspective view illustrating a conventional hinge device;

FIG. 2 is an assembled perspective view illustrating an electronic apparatus comprising a hinge device according to a first embodiment of the present invention;

FIG. 3 is an exploded perspective view illustrating the hinge device according to the first embodiment;

FIG. 4 is an assembled perspective view illustrating the hinge device according to the first embodiment;

FIG. 5 is another exploded perspective view of the hinge device according to the first embodiment from a different angle;

FIG. 6 is an exploded perspective view of the hinge device according to a second embodiment of the present invention;

FIG. 7 is an assembled perspective view illustrating the hinge device according to the second embodiment;

FIG. 8 is an exploded perspective view illustrating the hinge device according to a third embodiment of the present invention;

FIG. 9 is an assembled perspective view illustrating the hinge device according to the third embodiment; and

FIG. 10 is an assembled perspective view illustrating the hinge device according to a fourth embodiment of the present invention.

### DETAILED DESCRIPTION OF THE EMBODIMENTS

The above-mentioned and other technical contents, features, and effects of this invention will be clearly presented from the following detailed description of the four embodiments in coordination with the reference drawings.

Before this invention is described in detail, it should be noted that, in the following description, similar elements are designated by the same reference numerals.

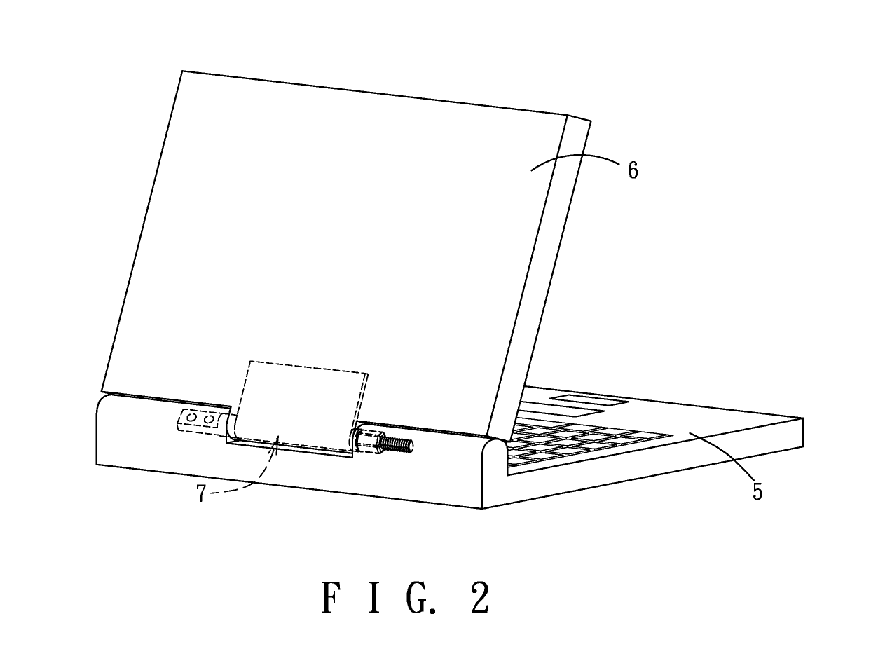

FIG. 2 illustrates a first embodiment of a hinge device 7 according to the present invention and an electronic apparatus comprising the hinge device 7. The electronic apparatus includes a first unit 5 such as a host casing of a notebook computer, a second unit 6 such as a housing for a screen of the notebook computer, and the hinge device 7 that connects the first unit 5 and the second unit 6. The hinge device 7 enables the first unit 5 and the second unit 6 to pivot relative to each other, and keeps the first unit 5 and the second unit 6 in a fixed position relative to each other when no external force is applied.

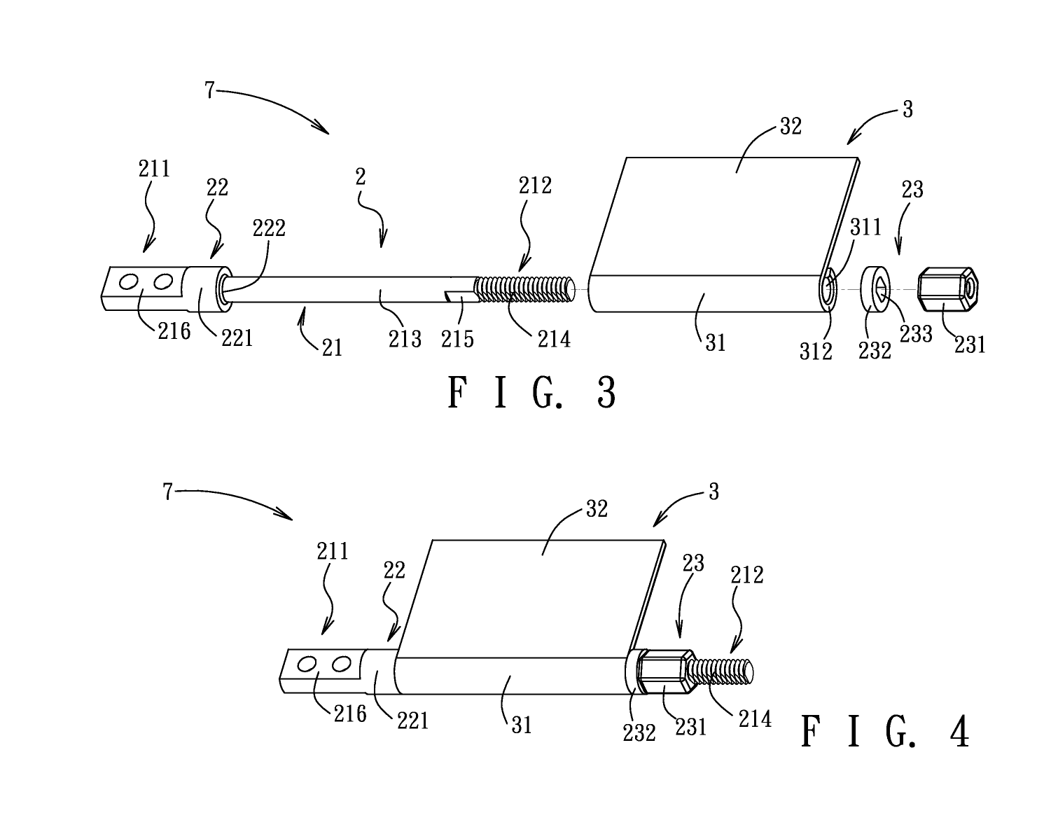

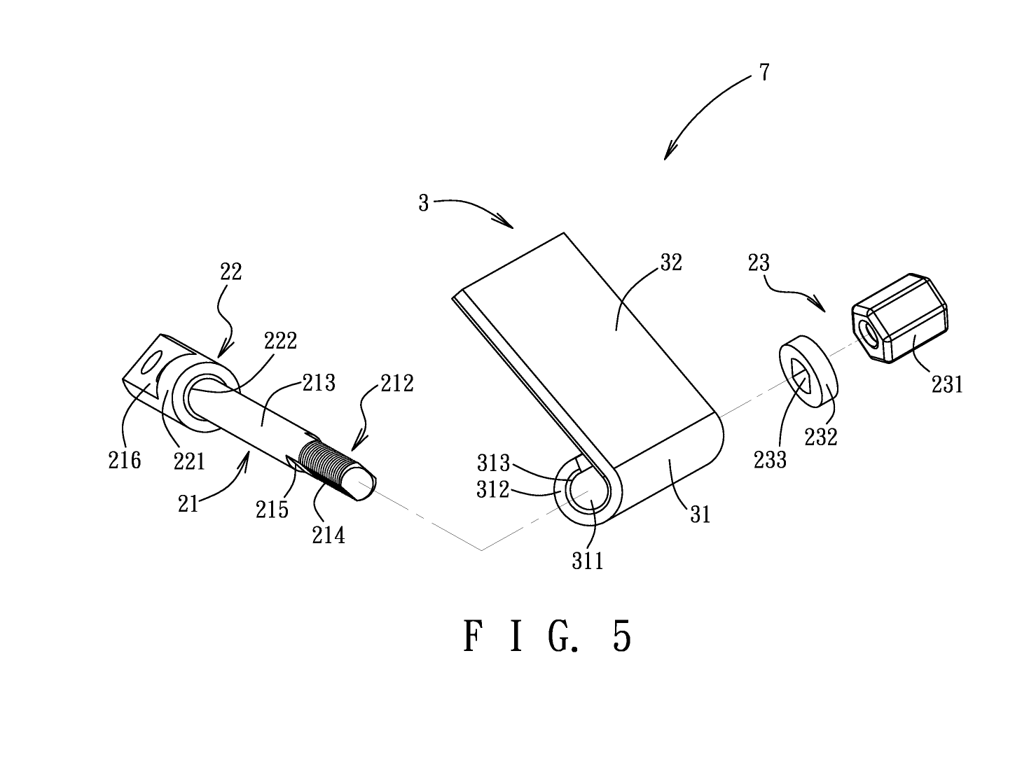

Further referring to FIGS. 3 to 5, the hinge device 7 includes a shaft unit 2 removably disposed on the first unit 5 and a coupling member 3 coupled to the second unit 6. The shaft unit 2 includes a shaft 21, a first positioning mechanism 22 and a second positioning mechanism 23. The shaft 21 includes a first positioning segment 211 and a second positioning segment 212 respectively corresponding to two opposite ends of the shaft 21, and a supporting segment 213 disposed between the first positioning segment 211 and the second positioning segment 212. The first positioning segment 211 includes a securing portion 216 with a non-circular cross-section. Specifically, in this embodiment, the securing portion 216 is in a flat-plate shape and has two perforations so that the securing portion 216 may be fastened to the first unit 5 through screw fastening, hot-melt bonding, or rivet connection or the like. The second positioning segment 212 has a threaded portion 214 that is formed with threads, and a limiting portion 215 that is connected between the threaded portion 214 and the supporting segment 213 and that has a non-circular cross-section.

The first positioning mechanism 22 is disposed at the first positioning segment 211 and is sandwiched between the securing portion 216 and the supporting segment 213. In this embodiment, the first positioning mechanism 22 includes a stop portion 221 disposed around the first positioning segment 211 and formed integrally as one piece with the shaft 21. The shaft unit 2 further includes a first chamfer 222, which is formed at a junction of the stop portion 221 and the shaft 21.

The second positioning mechanism 23 is removably disposed at the second positioning segment 212, and includes a screw nut 231 that is threadedly and removably engaged with the threaded portion 214 and a wear-resistant disc 232 that is sleeved on the limiting portion 215. The wear-resistant disc 232 has a limiting hole 233 in a shape matching the shape of the non-circular cross-section of the limiting portion 215, so that the wear-resistant disc 232, when sleeved on the limiting portion 215, will not rotate relative to the limiting portion 215. The wear-resistant disc 232 and the screw nut 231 are configured to abut against each other, so that the screw nut 231 is prevented from rotating relative to the shaft 21 to be disengaged from the same due to accidental vibration or collision.

The coupling member 3 includes a surrounding portion 31 rotatably surrounding the supporting segment 213 of the shaft 21 and an engaging portion 32 extending from the surrounding portion 31 in a direction away from the shaft 21. The engaging portion 32 is used for coupling to the second unit 6. The surrounding portion 31 has an inner friction surface 311 surrounding the outer surface of the supporting segment 213 and two side friction surfaces 312 respectively disposed on two opposite sides of the surrounding portion 31. The surrounding portion 31 is formed at an end of the inner friction surface 311 that is adjacent to the first chamfer 222 with a second chamfer 313 in a shape corresponding and complementary to the first chamfer 222 (i.e., in this embodiment, the first chamfer 222 is convex-shaped and the second chamfer 313 is concave-shaped). The inner friction surface 311 and the outer surface of the supporting segment 213 are in a close-fitting contact to produce a first frictional force for preventing relative rotation of the surrounding portion 31 and the supporting segment 213.

The screw nut 231 of the second positioning mechanism 23 is screwed onto the threaded portion 214 in a direction towards the first positioning mechanism 22 to allow the surrounding portion 31 of the coupling member 3 to be sandwiched between the first positioning mechanism 22 and the second positioning mechanism 23, such that the two side friction surfaces 312 of the surrounding portion 31 respectively abut against the stop portion 221 of the first positioning mechanism 22 and the wear-resistant disc 232 of the second positioning mechanism 23 to produce a second frictional force and a third frictional force respectively for preventing the relative rotation of the surrounding portion 31 and the supporting segment 213. Consequently, while the axial diameter and thus the outer surface area of the supporting segment 213 are reduced (that is, the area for producing the first frictional force is reduced), additional frictional forces, namely the second and third frictional forces, are produced between the surrounding portion 31 and the shaft unit 2, such that while the size of the hinge device 7 is reduced, the hinge device 7 still provides a torque sufficient to allow the first unit 5 and the second unit 6 to counter the gravity, vibration or collision to be in a fixed position relative to each other, thereby preventing damages of the first unit 5 and the second unit 6 due to accidental pivotal movement relative to each other.

The contact surfaces of the surrounding portion 31 and the shaft unit 2 for producing the frictional forces are subjected to a surface hardening treatment, that is, the inner friction surface 311 and the two side friction surfaces 312 of the surrounding portion 31, the surface of the stop portion 221 opposite to one of the side friction surfaces 312 and the surface of the wear-resistant disc 232 opposite to the other of the side friction surface 312 are all subjected to the surface hardening treatment. In this way, the contact surfaces may still produce the sufficient frictional forces after the hinge device 7 frequently suffers from rotational friction, thereby extending the service life of the hinge device 7. Furthermore, when the surrounding portion 31 rotates relative to the shaft 21, the stress caused by the torque produced by said rotation can be dispersed by the first chamfer 222 and thus not be concentratedly transmitted to the stop portion 221 through the supporting segment 213 of the shaft 21, thereby increasing the strength at the junction of the stop portion 221 and the shaft 21. Moreover, by forming the second chamfer 313 that cooperates with the first chamfer 222, the surrounding portion 31 and the first chamfer 222 can be coupled to each other smoothly, preventing them from being damaged due to collision.

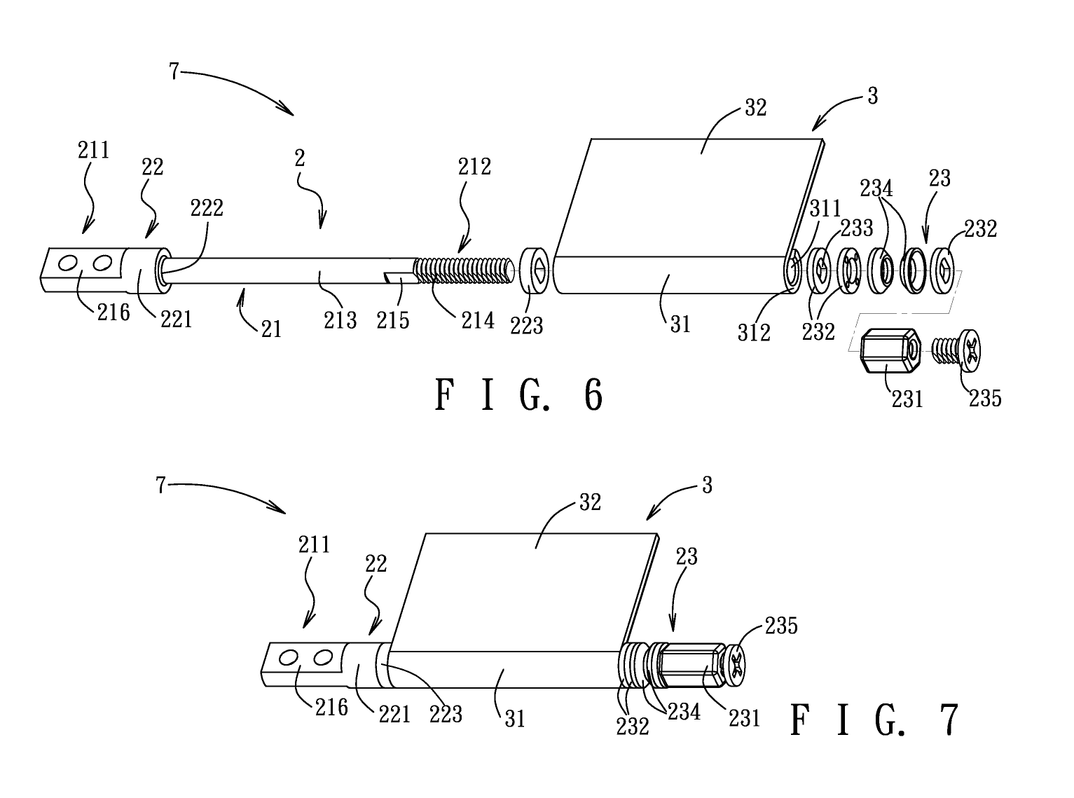

Referring to FIGS. 6 and 7, a second embodiment of the hinge device 7 according to the present invention is illustrated. In the second embodiment, the first positioning mechanism 22 further includes a wear-resistant disc 223 sleeved on the shaft 21 and sandwiched between the stop portion 221 and the surrounding portion 31 of the coupling member 3. The first positioning mechanism 22 produces the second frictional force by having the wear-resistant disc 223 abutting against a corresponding one of the side friction surfaces 312 of the surrounding portion 31. Accordingly, for the first positioning mechanism 22, the side surface of the stop portion 221 opposite to the surrounding portion 31 is not required to be treated by the surface hardening process, as long as the wear-resistant disc 223 is made of a material that is subjected to the surface hardening treatment, thus reducing the processing complexity. Hereafter, the wear-resistant disc 223 of the first positioning mechanism 22 is also referred to as the first wear-resistant disc 223, and the wear-resistant disc 232 of the second positioning mechanism 23 is also referred to as the second wear-resistant disc 232.

Furthermore, in the second embodiment, in accordance with the design requirement, the second positioning mechanism 23 includes a plurality of the second wear-resistant discs 232, and further includes two Belleville washers 234 sleeved on the shaft 21 and abutting respectively against the second wear-resistant discs 232 and against each other, and a screw fastener 235 screwed in the screw nut 231 at an end distal from the second wear-resistant discs 232. With the use of multiple second wear-resistant discs 232, it is unnecessary to specifically select a single wear-resistant disc having an axial length that matches the length of the limiting portion 215 to serve as the second wear-resistant disc 232, so long as an appropriate number of the second wear-resistant discs 232 are employed in accordance with the design requirement to match the length of the limiting portion 215, and additionally, the stress produced by screwing the screw nut 231 onto the threaded portion 214 can be evenly distributed over a corresponding one of the side friction surfaces 312 of the surrounding portion 31. When the screw nut 231 is screwed towards the second wear-resistant discs 232, the Belleville washers 234 are pressed so that slight compression and deformation occur in the axial direction for the Belleville washers 234 to produce a normal force to the second wear-resistant discs 232 in the axial direction. Thereby, even if abrasion occurs after a long-term use of the hinge device 7, due to the normal force provided by the Belleville washers 234, the second wear-resistant discs 232 may still properly abut against the corresponding side friction surface 312 of the surrounding portion 31 to produce the third frictional force of a sufficient degree. With the provision of the screw fastener 235 screwed into the screw nut 231, the screw nut 231 may be further secured, thus preventing the screw nut 231 from being disengaged from the threaded portion 214.

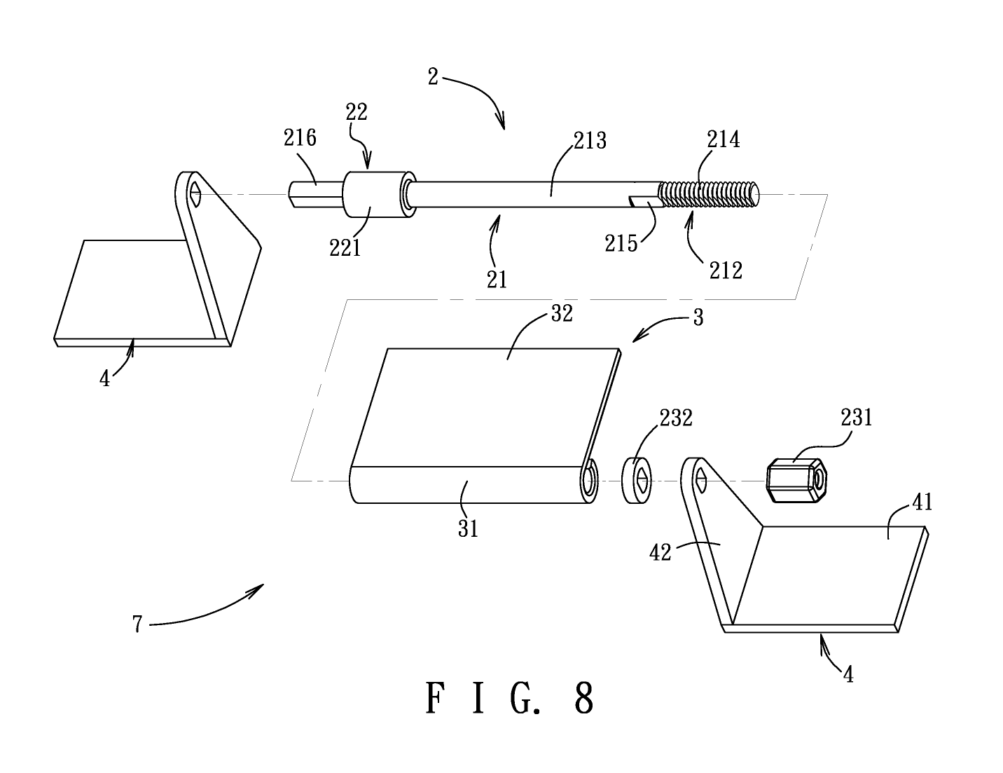

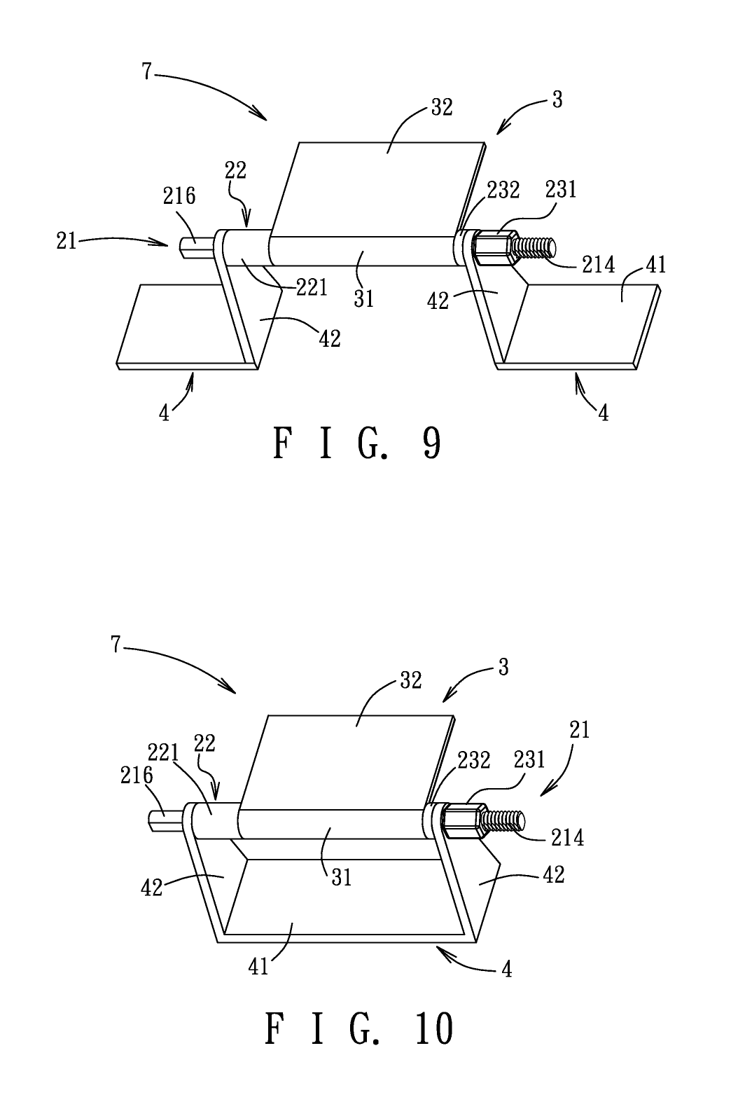

Referring to FIGS. 8 and 9, a third embodiment of the hinge device 7 according to the present invention is illustrated. In the third embodiment, the hinge device 7 further includes two support stands 4 that cooperatively support the shaft 21. Each of the two support stands 4 includes a base wall 41 and a connecting wall 42 substantially perpendicular to the base wall 41. The hinge device 7 is secured to the first unit 5 (see FIG. 2) by the base walls 41. The connecting walls 42 are disposed opposite to and spaced from each other. The securing portion 216 of the shaft 21 extends through and is fixed to the connecting wall 42 of one of the support stands 4, and the limiting portion 215 extends through and is fixed to the connecting wall 42 of the other of the support stands 4. The connecting wall 42 of each support stand 4 has a non-circular hole for the securing portion 216 or the limiting portion 215 to extend therethrough. Thereby, relative pivotal movement does not occur between the connecting wall 42 and the corresponding securing portion 216 or limiting portion 215.

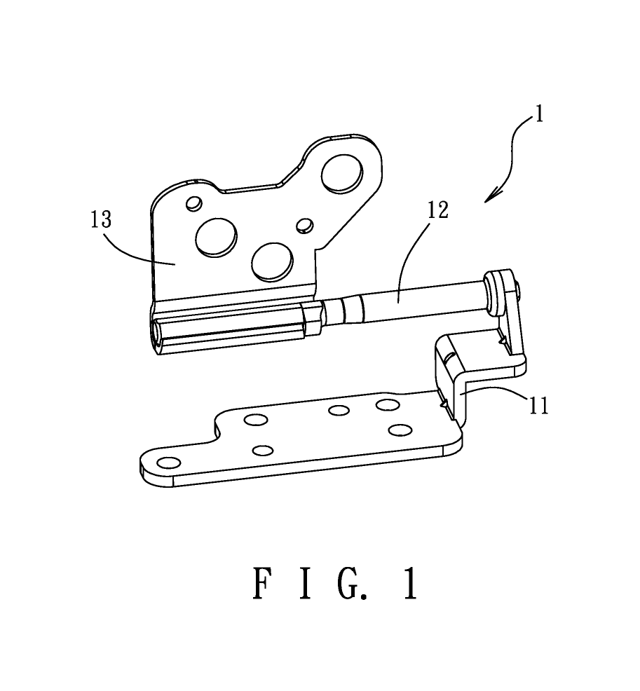

The two support stands 4 respectively support the portions of the shaft 21 that are located on two opposite sides of the coupling member 3, such that the shaft 21 and the support stands 4 form a beam structure, which provides better stability as compared with the cantilever structure formed by the shaft 12 and the support stand 11 in the prior art (see FIG. 1), such that the second unit 6 (see FIG. 2) connected to the shaft 21 through the coupling member 3 will not easily wobble relative to the first unit 5 fastened to the support stands 4, thus reducing the probability of damaging the first unit 5 and the second unit 6 as caused by vibrations.

Referring to FIG. 10, a fourth embodiment of the hinge device 7 according to the present invention is illustrated. In the fourth embodiment, the hinge device 7 includes only one support stand 4 for supporting the shaft 21, and the support stand 4 includes a base wall 41 and two connecting walls 42 spaced apart from each other and substantially perpendicular to the base wall 41. The securing portion 216 of the shaft 21 extends through and is fixed to one of the connecting walls 42, and the limiting portion 215 (as shown in FIG. 8) extends through and is fixed to the other of the connecting walls 42. Since the base wall 41 is located between the two connecting walls 42, the space to the outer sides of the connecting walls 42 is not occupied, thereby further reducing the size of the hinge device 7 as compared with the third embodiment.

It should be particularly emphasized that in the hinge device 7 of the present invention, the screw nut 231 is screwed onto the threaded portion 214 in a direction towards the first positioning mechanism 22 to produce a compression force that presses the two side friction surfaces 312 (as shown in FIG. 3) of the surrounding portion 31 respectively to abut against the first positioning mechanism 22 and the second positioning mechanism 23 to produce the second and third frictional forces, regardless of the angle at which the coupling member 3 is rotated relative to the shaft 21, the hinge device 7 is provided with a force sufficient to keep the first unit 5 and the second unit 6 remain in a fixed position relative to each other.

To sum up, with the two side friction surfaces 312 respectively in close-fitting contact with the first positioning mechanism 22 and the second positioning mechanism 23, the surrounding portion 31 is able to produce the second and third frictional force in addition to the first frictional force even when the supporting segment 213 has a limited outer surface area, so that the hinge device 7 with a reduced size may still have the sufficient force to maintain the relative position of the shaft unit 2 and the coupling member 3. Furthermore, with the two side friction surfaces 312 sharing the stress burden caused by the torque produced by the supporting segment 213, and the first and second chamfers 222, 313 avoiding the concentration of the stress on the shaft 21, the shaft 21 may not break easily and thus has an extended service life. In addition, through the support stand(s) 4 with two connecting walls 42, the shaft unit 2 can be supported through a beam structure which is more stable than the cantilever structure in the prior art, and thus damaging to the first unit 5 and the second unit 6 of the electronic apparatus comprising the hinge 7 is prevented due to the small likelihood of wobbling. Thus, the objects of the present invention can indeed be achieved.

While the present invention has been described in connection with what are considered the most practical embodiments, it is understood that this invention is not limited to the disclosed embodiments but is intended to cover various arrangements included within the spirit and scope of the broadest interpretation so as to encompass all such modifications and equivalent arrangements.

What is claimed is:

1. A hinge device, comprising:
a shaft unit including a shaft, a first positioning mechanism and a second positioning mechanism, said shaft including a first positioning segment and a second positioning segment at two opposite ends of said shaft and a supporting segment between said first positioning segment and said second positioning segment, said first positioning segment including a securing portion, said second positioning segment including a threaded portion, said first positioning mechanism being disposed at said first positioning segment between said securing portion and said supporting segment and including a stop portion that is disposed on said first positioning segment and that is formed integrally as one piece with said shaft, said second positioning mechanism being disposed at said second positioning segment and including a screw nut that is screwed on said threaded portion; and
a coupling member including a surrounding portion that rotatably surrounds said supporting segment of said shaft and an engaging portion that extends from said surrounding portion in a direction away from said shaft, said surrounding portion having an inner friction surface that surrounds an outer surface of said supporting segment and two side friction surfaces that are respectively at two opposite sides of said surrounding portion, said inner friction surface and said outer surface of said supporting segment being in contact with each other so as to produce a first frictional force, said screw nut being screwed in a direction towards said first positioning mechanism to allow said surrounding portion of said coupling member to be sandwiched between said first positioning mechanism and said second positioning mechanism, such that said two side friction surfaces of said coupling member respectively abut against said first positioning mechanism and said second positioning mechanism to respectively produce a second friction force and a third friction force therewith.

2. The hinge device of claim 1, wherein said inner friction surface and said side friction surfaces of said surrounding portion, said outer surface of said supporting segment and surfaces of said shaft unit in contact with said side friction surfaces are all subjected to a surface hardening treatment.

3. The hinge device of claim 1, wherein said shaft unit further includes a first chamfer, which is formed at a junction of said stop portion and said shaft.

4. The hinge device of claim 3, wherein said surrounding portion of said coupling member abuts against said stop portion of said first positioning mechanism, and is formed at an end of said inner friction surface that is adjacent to said first chamfer with a second chamfer in a shape corresponding to said first chamfer.

5. The hinge device of claim 1, wherein said first positioning mechanism further includes at least one first wear-resistant disc that is sleeved on said shaft and that is sandwiched between said stop portion and said surrounding portion of said coupling member.

6. The hinge device of claim 1, wherein said second positioning segment further includes a limiting portion that connects said threaded portion and said supporting segment and that has a non-circular cross-section, said second positioning mechanism further including at least one second wear-resistant disc that is sleeved on said limiting portion and that is sandwiched between said surrounding portion of said coupling member and said screw nut, said second wear-resistant disc abutting against a corresponding one of said side friction surfaces of said surrounding portion.

7. The hinge device of claim 6, wherein said second wear-resistant disc has a limiting hole in a shape matching the shape of said cross-section of said limiting portion.

8. The hinge device of claim 6, wherein said second positioning mechanism further includes at least one Belleville washer that is sleeved on said shaft and that abuts against said second wear-resistant disc.

9. The hinge device of claim 6, wherein said second positioning mechanism further includes a screw fastener screwed in said screw nut at an end distal from said second wear-resistant disc.

10. The hinge device of claim 1, wherein said second positioning segment further includes a limiting portion that connects said threaded portion and said supporting segment, said hinge device further comprising two support stands that cooperatively support said shaft, each of said two support stands including a base wall and a connecting wall that is substantially perpendicular to said base wall, said connecting walls being disposed opposite to and spaced from each other, said securing portion of said shaft extending through and being fixed to said connecting wall of one of said support stands, said limiting portion extending through and being fixed to said connecting wall of the other of said support stands.

11. The hinge device of claim 1, wherein said second positioning segment further includes a limiting portion that connects said threaded portion and said supporting segment, said hinge device further comprising a support stand that supports said shaft, said support stand including a base wall and two connecting walls that are spaced from each other and that are substantially perpendicular to said base wall, said securing portion of said shaft extending through and being fixed to one of said connecting walls, said limiting portion extending through and being fixed to the other of said connecting walls.

12. An electronic apparatus comprising a first unit, a second unit and a hinge device that connects said first unit and said second unit, said hinge device enabling said first unit and said second unit to pivot relative to each other and including:
a shaft unit including a shaft, a first positioning mechanism and a second positioning mechanism, said shaft including a first positioning segment and a second positioning segment at two opposite ends of said shaft, and a supporting segment between said first positioning segment and said second positioning segment, said first positioning segment including a securing portion that is fastened to said first unit, said second positioning segment including a threaded portion, said first positioning mechanism being disposed at said first positioning segment between said securing portion and said supporting segment and including a stop portion that is disposed on said first positioning segment and that is formed integrally as one piece with said shaft, said second positioning mechanism being disposed at said second positioning segment and including a screw nut that is screwed on said threaded portion; and
a coupling member including a surrounding portion that rotatably surrounds said supporting segment of said shaft and an engaging portion that extends from said surrounding portion in a direction away from said shaft and that is secured to said second unit, said surrounding portion having an inner friction surface that surrounds an outer surface of said supporting segment and two side friction surfaces that are respectively located on two opposite sides of said surrounding portion, said inner friction surface and said outer surface of said supporting segment being in contact with each other so as to produce a first frictional force, said screw nut being screwed onto said threaded portion in a direction towards said first positioning mechanism to allow said surrounding portion of said coupling member to be sandwiched between said first positioning mechanism and said second positioning mechanism, such that said two side friction surfaces of said coupling member respectively abut against said first positioning mechanism and said second positioning mechanism to respectively produce a second frictional force and a third frictional force therewith.

13. The electronic apparatus of claim 12, wherein said inner friction surface and said side friction surfaces of said surrounding portion, said outer surface of said supporting segment and surfaces of said shaft unit in contact with said side friction surfaces are all subjected to a surface hardening treatment.

14. The electronic apparatus of claim 12, wherein said shaft unit further includes a first chamfer, which is formed at a junction of said stop portion and said shaft.

15. The electronic apparatus of claim 14, wherein said surrounding portion of said coupling member abuts against said stop portion of said first positioning mechanism, and is formed at an end of said inner friction surface that is adjacent to said first chamfer with a second chamfer in a shape corresponding to said first chamfer.

16. The electronic apparatus of claim 12, wherein said first positioning mechanism further includes at least one first wear-resistant disc that is sleeved on said shaft and that is sandwiched between said stop portion and said surrounding portion of said coupling member.

17. The electronic apparatus of claim 12, wherein said second positioning segment further includes a limiting portion that connects said threaded portion and said supporting segment and that has a non-circular cross-section, said second positioning mechanism further including at least one second wear-resistant disc that is sleeved on said limiting portion and that is sandwiched between said surrounding portion of said coupling member and said screw nut, said second wear-resistant disc abutting against a corresponding one of said side friction surfaces of said surrounding portion; and
wherein said second wear-resistant disc has a limiting hole in a shape matching the shape of said cross-section of said limiting portion.

18. The electronic apparatus of claim 17, wherein said second positioning mechanism further includes at least one Belleville washer that is sleeved on said shaft and that abuts against said second wear-resistant disc, and a screw fastener screwed in said screw nut at an end distal from said second wear-resistant disc.

19. An electronic apparatus comprising a first unit, a second unit and a hinge device that connects said first unit and said second unit, said hinge device enabling said first unit and said second unit to pivot relative to each other and including:
a shaft unit including a shaft, a first positioning mechanism and a second positioning mechanism, said shaft including a first positioning segment and a second positioning segment at two opposite ends of said shaft and a supporting segment between said first positioning segment and said second positioning segment, said first positioning segment including a securing portion, said second positioning segment including a threaded portion and a limiting portion that connects said threaded portion and said supporting segment, said first positioning mechanism being disposed at said first positioning segment between said securing portion and said supporting segment and including a stop portion that is disposed on said first positioning segment and that is formed integrally as one piece with said shaft, said second positioning mechanism being disposed at said second positioning segment and including a screw nut that is screwed on said threaded portion;
two support stands cooperatively supporting said shaft and each including a base wall that is secured to said first unit and a connecting wall that is substantially perpendicular to said base wall, said connecting walls being disposed opposite to and spaced from each other, said securing portion of said shaft extending through and being fixed to said connecting wall of one of said support stands, said limiting portion extending through and being fixed to said connecting wall of the other of said support stands; and
a coupling member including a surrounding portion that rotatably surrounds said supporting segment of said shaft and an engaging portion that extends from said surrounding portion in a direction away from said shaft and that is secured to said second unit, said surrounding portion having an inner friction surface that surrounds an outer surface of said supporting segment and two side friction surfaces that are respectively located on two opposite sides of said surrounding portion, said inner friction surface and said outer surface of said supporting segment being in contact with each other to produce a first frictional force, said screw nut being screwed onto said threaded portion in a direction towards said first positioning mechanism to allow said surrounding portion of said coupling member to be sandwiched between said first positioning mechanism and said second positioning mechanism, such that said two side friction surfaces of said coupling member respectively abut against said first positioning mechanism and said second positioning mechanism to respectively produce a second frictional force and a third frictional force therewith.

20. An electronic apparatus comprising a first unit, a second unit and a hinge device that connects said first unit and said second unit, said hinge device enabling said first unit and said second unit to pivot relative to each other and including:
a shaft unit including a shaft, a first positioning mechanism and a second positioning mechanism, said shaft including a first positioning segment and a second positioning segment at two opposite ends of said shaft and a supporting segment between said first positioning segment and said second positioning segment, said first positioning segment including a securing portion, said second positioning segment including a threaded portion and a limiting portion that connects said threaded portion and said supporting segment, said first positioning mechanism being disposed at said first positioning segment between said securing portion and said supporting segment and including a stop portion that is disposed on said first positioning segment and that is formed integrally as one piece with said shaft, said second positioning mechanism being disposed at said second positioning segment and including a screw nut that is screwed on said threaded portion;
a support stand supporting said shaft and including a base wall that is secured to said first unit and two connecting walls that are substantially perpendicular to said base wall and that are disposed opposite to and spaced from each other, said securing portion of said shaft extending through and being fixed to one of said connecting walls, said limiting portion extending through and being fixed to the other of said connecting walls; and
a coupling member including a surrounding portion that rotatably surrounds said supporting segment of said shaft and an engaging portion that extends from said surrounding portion in a direction away from said shaft and that is secured to said second unit, said surrounding portion including an inner friction surface that surrounds an outer surface of said supporting segment and two side friction surfaces that are respectively located on two opposite sides of said surrounding portion, said inner friction surface and said outer surface of said supporting segment being in contact with each other to produce a first frictional force, said screw nut being screwed onto said threaded portion in a direction towards said first positioning mechanism to allow said surrounding portion of said coupling member to be sandwiched between said first positioning mechanism and said second positioning mechanism, such that said two side friction surfaces of said coupling member respectively abut against said first positioning mechanism and said second positioning mechanism to respectively produce a second frictional force and a third frictional force therewith.
